(19) United States
(12) Patent Application Publication
(10) Pub. No.: US 2025/0024597 A1
(43) Pub. Date: Jan. 16, 2025

(54) FLEXIBLE AUTOMOTIVE GRADE LIGHT SOURCE

(71) Applicant: LUMILEDS LLC, San Jose, CA (US)

(72) Inventors: Christian KLEIJNEN, Ell (NL); Frank GIESE, Aachen (DE); Hua Sin YEW, Bayan Lepas (MY); Georg Friedrich Alfons HENNINGER, Aachen (DE)

(73) Assignee: LUMILEDS LLC, San Jose, CA (US)

(21) Appl. No.: 18/771,507

(22) Filed: Jul. 12, 2024

Related U.S. Application Data
(60) Provisional application No. 63/513,195, filed on Jul. 12, 2023.

(51) Int. Cl. H05K 1/03; H05K 1/11; H05K 1/14; H05K 1/18

(52) U.S. Cl. CPC H05K 1/0393; H05K 1/116; H05K 1/141; H05K 1/181; H05K 2201/09381; H05K 2201/10106

(57) ABSTRACT

A flexible foil printed circuit board substrate is provided. The flexible foil printed circuit board substrate includes at least first and second lands and a flex foil area between pairs of the at least first and second lands. Each of the first and second lands can receive a placement of one or more surface mounting technology components. The flex foil area can include at least two layers including conductive portions connecting the at least first and second lands. The flex foil area can include one or more curved shapes. Outermost ends of the flex foil area can be integrated into the at least first and second lands.

### CROSS-REFERENCE TO RELATED APPLICATIONS

This application claims the benefit of U.S. Provisional Application No. 63/513,195, filed Jul. 12, 2023, the contents of which are incorporated herein by reference.

### BACKGROUND

Conventional technologies in the automotive industry have trended to slim, strip-like lighting solutions, both for interior and exterior lighting functions. And new styling solutions for car interior and exterior illumination (e.g., white light strips for position lighting, amber light strips for signaling, and red light strips for stop/tail functions) are continued to be sought after. In this regard, contour line, roof rail, and grill illumination have become popular. Yet, these applications require homogeneous line emitters, as well as light emitting surfaces (“coins”), that include inherent disadvantages.

For example, a disadvantage of conventional technologies is a cost structure due to a complex build-up of individual wires connecting interposer boards to form an electrical circuit. In this regard, the cost structure requires expensive components that are individually assembled by an expensive surface mounting technology (“SMT”) assembly process, with a multitude of solder joints in one homogeneous line emitter. In addition, because wires are mounted on a backside of an interposer board of the homogeneous line emitter and light emitting diodes (“LEDs”) are mounted on a frontside of the interposer board, a resulting carrier that embedded in silicone to shape the homogeneous line emitter is rather thick.

As another example, a disadvantage of conventional technologies is a lack of real three-dimensional (“3D”) flexibility and an inability to withstand harsh automotive use conditions due to larger dimensions found in conventional technologies with or without integration into silicone.

Thus, a solution is needed.

### SUMMARY

According to one or more embodiments, a flexible foil printed circuit board substrate is provided. The flexible foil printed circuit board substrate includes at least first and second lands and a flex foil area between pairs of the at least first and second lands. Each of the first and second lands can receive a placement of one or more surface mounting technology components. The flex foil area can include at least two layers including conductive portions connecting the at least first and second lands. The flex foil area can include one or more curved shapes. Outermost ends of the flex foil area can be integrated into the at least first and second lands.

According to one or more embodiments, a flexible automotive grade light source includes a flexible foil printed circuit board substrate. The flexible foil printed circuit board substrate includes at least first and second lands and a flex foil area between pairs of the at least first and second lands. Each of the first and second lands can receive a placement of one or more surface mounting technology components. The flex foil area includes at least two layers including conductive portions connecting the at least first and second lands. The flex foil area can include one or more curved shapes. The outermost ends of the flex foil area can be integrated into the at least first and second lands. The flexible foil printed circuit board substrate can be embedded in a silicone matrix of the flexible automotive grade light source.

### BRIEF DESCRIPTION OF THE DRAWINGS

A more detailed understanding can be had from the following description, given by way of example in conjunction with the accompanying drawings wherein:

FIG. 1 shows a process flow according to one or more embodiment;

FIG. 2 shows schematics according to one or more embodiments;

FIG. 3 shows a schematic according to one or more embodiments;

FIG. 4 shows a schematic according to one or more embodiments;

FIG. 5 shows a schematic according to one or more embodiments;

FIG. 6 shows a schematic according to one or more embodiments;

FIG. 7 shows a schematic according to one or more embodiments;

FIG. 8 shows a schematic according to one or more embodiments;

FIG. 9 is a diagram of an example vehicle headlamp system; and

FIG. 10 is a diagram of another example vehicle headlamp system.

### DETAILED DESCRIPTION

According to one or more embodiments, described herein is a flexible automotive grade light source. Generally, the flexible automotive grade light source overcomes the disadvantages of conventional technologies and while providing additional advantages of a 3D LED carrier in a silicon solution and a LED on thin flexible substrate solution. In this regard, the flexible automotive grade light source is a more cost-effective light source that can be small size, have a high flexibility, have a high light flux, have a high homogeneity, and include automotive grade robustness with inexpensive components.

By way of example, the flexible automotive grade light source can utilize a specially shaped flexible foil printed circuit board assembly (“PCBA”) build-up including a flexible 3D LED light source. Note that the flexible foil PCBA can also be referred to herein as a thin film flexible foil PCBA. The specially shaped flexible foil PCBA replaces wires and interposers of conventional technologies. The specially shaped flexible foil PCBA includes electrical connection schemes where two or three electrical lines per metal layer enable multiple metal lines. In this regard, two metal layers with two electrical lines each enable four electrical lines that allow more flexibility to electrically connect the flexible 3D LED light source compared to the conventional technologies, where the number of electrical lines is limited to three due to space availability. Note that, while the flexible automotive grade light source can be designed to have more than three electrical lines per layer, the examples herein discuss two or three electrical lines per metal layer in view of automotive reliability requirements for automotive applications. Additionally, the two or three electrical lines per metal layer can include segments (e.g., three or more bends, such as five (5) bends or semi-circles/half-sines segments) constructed to withstand automotive reliability requirements.

Examples of different light illumination systems and/or light emitting diode (“LED”) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout. Further, LEDs may have a relatively large light emitting region with outer walls surrounded on at least one side by very thing reflectors, such as dichroic mirrors, which may enable very close spacing of the LEDs, such as described above, while still maintaining a contrast between neighboring LEDs. In some embodiments, the reflectors may only be placed in locations where the side wall is adjacent a side wall of a neighboring LED. For such LEDs, standard pick and place techniques may be difficult for the reasons described above, particularly as the close spacing makes any movement of the LEDs problematic for their functionality.

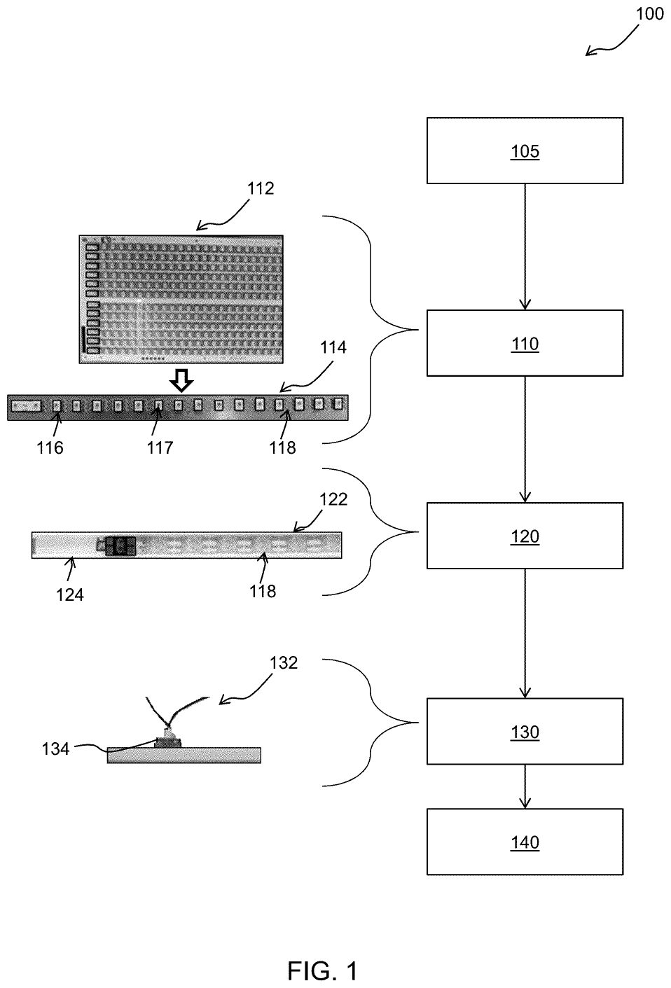

FIG. 1 shows a process flow 100 according to one or more embodiments. Generally, the process flow 100 is a method for making a flexible automotive grade light source, such as a build-up of a three-dimensional (“3D”) LED product.

The process flow 100 begins, at block 105, where a panel is manufactured to include a plurality of modules, each of which will become flexible automotive grade light sources at the conclusion of the process flow 100. The panel can be a PCBA that can further be sub-divided into the plurality of modules or smaller PCBA assemblies. According to one or more embodiments, the PCBA and the smaller PCBAs can be flexible foil PCBAs (also referred to as specially shaped thin film flexible foil PCB substrate build-ups, flexible foil PCB substrates, and thin film flexible foil PCBAs).

At block 110, a cutting or punching process is performed on the panel. For example, a laser cutting is performed on the panel. An example of the panel includes a front end panel 112. The front end panel 112 is laser cut to provide one or more front end strings 114. Each front end string 114 can include an interposer 116, a LED 117, and a s-wire 118. According to one or more embodiments, to be reliable for automotive applications, the PCBA includes the interposers 116 on which the LEDs are soldered and connected by the s-wire 118 (e.g., custom made specially shaped) to form the electric circuit. According to one or more embodiments, the LED is smaller than a width of the 3D LED product.

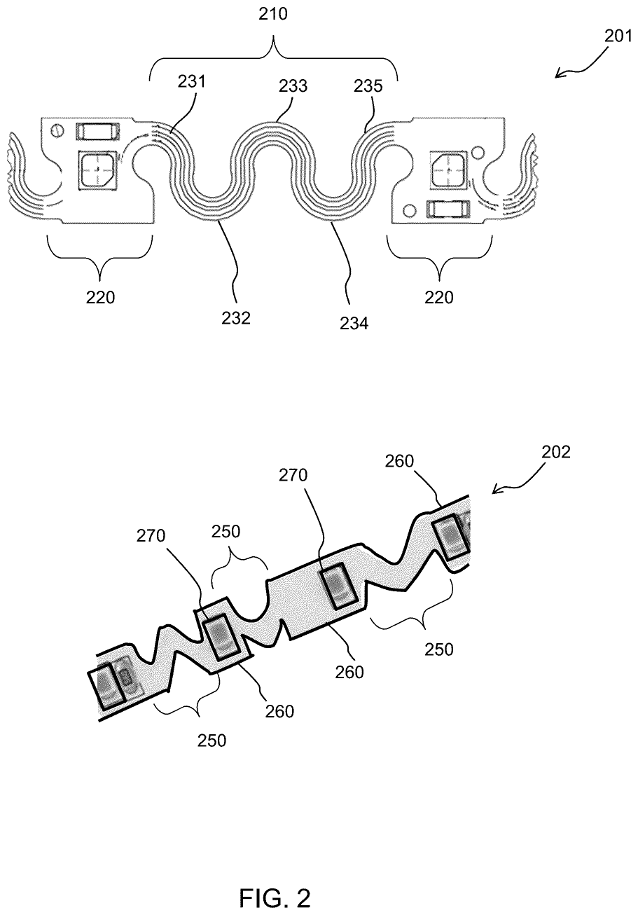

FIG. 2 shows schematics 201 and 202 according to one or more embodiments. The schematics 201 and 202 can be examples of build-ups of flexible foil printed circuit board (“PCB”) substrate that provide the s-wires 118 between the LEDs 117. According to one or more embodiments, using specially shaped flexible foil PCB substrate build-up, a flexible 3D LED light source can be created where the flexible foil PCB substrate is replacing the wires and interposers carrying LEDs of the conventional technologies.

According to one or more embodiments, and as shown in the schematics 201, the flexible foil PCB substrate can be constructed such that an area 210 between lands 220 (pairs of the two or more lands) on which the LEDs are placed (“LED lands”) include any number of curved shapes/geometries to mimic winding river, serpentine or snake-like, parabolic, ellipsoidal, and/or sinusoidal shapes. The lands 220 can be of any shapes/geometries, such as rectangular or an irregular shape, and can be configured to receive a placement of SMT components (e.g., the LEDs, microcontrollers, etc.).

By way of example, a circular-sinusoidally shaped area 210 can include at least three sections 231, 232, and 235. The two outermost sections 231 and 235 terminate into the LED lands 220 (e.g., an outer boarder characterizing lands). As shown, quarter circles or half sines are drawn into and integrated in the LED lands 220. According to one or more embodiments, the circular-sinusoidally shaped area 210 can include five sections 231, 232, 233, 234, and 235, with the interior sections 232, 233, and 235 being half circular or half sinusoidal shapes. By way of example, each section 231, 232, 233, 234, and 235 can be horizontally flipped relative to the previous or next section (e.g., a shifted mirror of an adjacent section). According to one or more embodiments, the five sections 231, 232, 233, 234, and 235 can have a lower amplitude at a height of the lands 220.

According to one or more embodiments, the at least three sections 231, 232, and 235 can be characterized by an outer boarder line (e.g., an outer boarder of the bent segments), an inner boarder line (e.g., an inner boarder of the bent segments), and two straight lines connecting the ends of the two boarder lines in the shortest way. These straight lines are helping lines only where the at least three sections 231, 232, and 235 are joined together. The inner border line of the outermost semi-circles/half-sines thereby continues to follow the half circular shape, with the consequence that the outermost “half sine” 231 and 235 consists of a “quarter sine” transitioning into a “quarter circle”. The inner border line at the end of the half circle then transfers into a spiral with opposite curvature as compared to the quarter circle within the LED land. In border cases, the spiral can become another semi-circle. By this the edge that would have formed on the land is cut away. The top border line of the semi-circle/half-sine is ending at the edge of the LED land, transitioning smoothly from the half circular/sinusoidal section to the straight LED land upper boarder. Altogether, the flexible foil PCB substrate shape minimizes a stress build-up during thermal cycling to a point that the PCBA can be reliably embedded into the silicone matrix to form the desired light source and meeting automotive reliability requirements.

According to one or more embodiments, and as shown in the schematics 202, the flexible foil PCB substrate can be constructed such that areas 250 between lands 260 on which LEDs 270 are placed (“LED lands”) include any number of curved shapes to mimic winding river, serpentine or snake-like, parabolic, ellipsoidal, and/or sinusoidal shapes. According to one or more embodiments, an outermost bent second area segments are partially integrated into a first area lands. Further, an inner boarder line of the segment continues into the first area land to form of a semi-circle, followed by a spiral of opposite turning direction to connect the integrated segments inner boarder line with the outer side of the land. Furthermore, an outer boarder line of the first half of the outermost segment in similar manner partly continues into the land and connects the segment boarder to the land boarder in a half circular or swinging curve.

Returning to the process flow 100, at block 120, a back end production is implemented on a rear side 122 of the front end panel 112. As shown in FIG. 1, the rear side 122 can the s-wire 118 and a dummy end 124.

At block 130, soldering is implemented on the rear side 122. As shown in image 132 of FIG. 1, the soldering is implemented to install an electrical contact 134 on the rear side 122. The electrical contact 134 can be representative of at least one connecting structure on at least one of a backside of one of the two or more lands for electrically connecting the one or more surface mounting technology components to a power source. Note that the rear side 122 can be referred to as a backside or second side. The rear side 122, the backside, or the second side being a same side as a flexible foil printed circuit board. According to one or more embodiments, a connecting structure is present on a backside of an outermost land (of the two or more lands). According to one or more embodiments, a connecting structure is on a backside of the flexible foil PCB substrate in between a two outermost lands of the two or more lands. According to one or more embodiments, two or more connecting structures is on a backside of an outermost land of the two or more lands. According to one or more embodiments, at least one connecting structure includes a rigid printed circuit board mounted on a backside of at least one of the two or more lands.

At block 140, each of the one or more front end strings 114 are inserted into a silicone matrix to provide the flexible automotive grade light sources. The silicone matrix can withstand automotive grade reliability requirements. According to one or more embodiments, the silicone matrix can include a white reflecting H-shaped outer optical mixing box, where a connecting horizontal bar of the H is asymmetrically drawn to a bottom of the H. Further, the flexible foil PCBA is placed into a first cavity of the H and rectangular holes that are punched into the connecting horizontal bar of the H receive the LEDs connected by the flexible foil PCBA to shine into a second cavity of the H. Note that the first cavity can be smaller than the second cavity. Note, also, that both cavities can be filled with clear silicone, where the clear silicone has a wavy surface structure on a top side that is filled and covered with diffusing silicone. The diffusing silicone can be characterized in that a maximum diffusor thickness of a wavy structure is placed above the LEDs while a minimum diffusor thickness spot is placed in between the LEDs. Additional round holes can be added in the connecting horizontal bar of the H to allow silicone diffusion through said bar during vacuum processing (e.g., which helps removing air bubbles in the flexible automotive grade light sources). Further, rectangular holes receiving the LEDs can be elongated towards the walls of an outer box to ease silicone diffusion through the connecting horizontal bar of the H during vacuum processing.

According to one or more embodiments, a light source (e.g., flexible automotive grade light sources) can include the flexible foil PCB substrate being embedded in the silicon matrix. According to one or more embodiments, at least corresponding light emitting areas of the one or more surface mounting technology components are embedded in a transparent silicone matrix. The silicon matrix can include a mixing box that homogenizes light emitted by the one or more surface mounting technology components. The transparent silicone matrix can include a reflecting silicone configured to reflect the light within the mixing box (e.g., reflect light in three directions, with a fourth direction being an exit). The mixing box can include a top layer of transparent silicone configured to homogenize the light, as the light exits the mixing box. The light source include flexibility in at least two dimensions (e.g., a vertical and a lateral direction). A side flexibility of the light source can be stiff (e.g., can include a stiffness in combination with the flexible foil PCB substrate).

That is, the result of the process flow 100 is the flexible automotive grade light source that can reliably operate in automotive exterior lighting use conditions. The flexible automotive grade light source provides a high freedom of styling.

According to one or more embodiments, each flexible automotive grade light source includes the PCBA embedded in the silicone matrix, that provides a light source with homogeneous high flux light output. Further, each flexible automotive grade light source (e.g., each 3D LED product) mechanically flexible, bi-axially bendable, and capable to meet the high automotive reliability requirements. Further, each flexible automotive grade light source be integrated directly as a shapeable line or combined with a suitable optical element to create an elongated light surface. According to one or more embodiments, each flexible automotive grade light source can include animation by segmenting. Segmenting can include an ability to turn on and off individual segments independent of the others, as is required in signaling or animated welcome light functions.

According to one or more embodiments, the flexible automotive grade light source can be constructed with a height selected from a range of 0.01 cm to 1.1 cm (e.g., 8 mm); a width selected from a range of 0.01 cm to 1.1 cm (e.g., 6 mm, 8 mm, or 1.0 cm); a light emitting area width selected from a range of 0.01 cm to 1.1 cm (e.g., 6 mm, 8 mm, or 1.0 cm); a total length selected from a range of 1 cm to 500 cm (e.g., 10 cm or 420 cm). By way of example, the flexible automotive grade light source can be a 8×8 mm2 elongated (up to 50 cm) light source with homogeneous high flux light output. The flexible automotive grade light source can provide a maximal allowable LED to LED pitch, and hence an oscillation of a wavy structure can be defined by a thickness of the thin light source. By way of example, a 22 mm LED to LED pitch can be used for 8 mm height to still preserve a homogeneity of the light emitted while reducing the components required per total length to the minimum. By way of another example, larger distance pitches of the flexible automotive grade light source are easier to manufacture compared to a wired approach of conventional technologies. In this regard, a maximum pitch can be dependent on a size of a mixing box of the flexible automotive grade light source. For instance, the flexible automotive grade light source (e.g., a 3D LED size of 6×8 mm2) can estimate a maximum LED to LED pitch of 22 mm when a homogeneous light output shall be maintained. According to one or more embodiments, the flexible automotive grade light source can include a three bend approach for the LED to LED pitches to be in a range of 10 to 25 mm (e.g., a small bay is required to relax the stress). According to one or more embodiments, the flexible automotive grade light source can include one bend approach for the LED to LED distances to be at or below 15 mm (e.g., an extreme bay is required to relax the stress).

According to one or more embodiments, the flexible automotive grade light source can include a light source with a light emitting area length comparable to the total length, a light source that is flexible in three dimensions, and a light source with the homogeneous light output from the light emitting surface. According to one or more embodiments, the flexible automotive grade light source can include a light source that can be illuminated at once (e.g., providing static illumination), a light source that can be illuminated in segments (e.g., providing dynamic illumination); and a light source that withstands automotive reliability requirements.

One or more technical effects, advantages, and benefits of the flexible foil PCB substrate (e.g., using a flex foil PCBs as carrier) include integrating a full electronic circuit while omitting custom made, special formed wires and rigid PCB interposers. Consequently, the bill of material cost is reduced, and the SMT mounting process is simplified (e.g., less components need to be joined).

One or more technical effects, advantages, and benefits of the flexible foil PCB substrate include connecting all LEDs in one circuit, thereby reducing a number of solder joints. A higher yield can be accumulated when using the flexible foil PCB substrate in manufacturing, as less solder joints can potentially fail during stress testing/in the field and lower costs to produce and maintain the product (e.g., in conventional technologies, as every solder joint poses the risk of yield loss and improved robustness).

One or more technical effects, advantages, and benefits of the flexible foil PCB substrate include a thinner total build-up of the flexible foil PCB substrate as the flex foil itself is thin and the remaining components are placed mainly on one side. According to one or more embodiments, with respect to a bridge PCB, the flexible foil PCB substrate can be adapted to a thinner build-up to enable or achieve an optical mixing box that has an increment in volume (e.g., a height from the LED to a diffusor). In turn, the flexible automotive grade light source that includes the flexible foil PCB substrate provides an optical benefit to achieve high uniformity with a larger LED pitch, as well as an improved heat management. The improved heat management of the flexible automotive grade light source enables the flexible automotive grade light source to pass all automotive reliability requirements and be used in many automotive applications, at considerably reduced cost compared to the wire based conventional technology solutions.

One or more technical effects, advantages, and benefits of the flexible foil PCB substrate being a carrier include integrating a full electronic circuit while omitting custom made, special formed wires and rigid PCB interposers. As a result, the bill of material cost is reduced. Further, the SMT mounting process is simplified, as less components need to be joined, reducing the total cost for the flexible foil PCB substrate.

One or more technical effects, advantages, and benefits of the flexible foil PCB substrate connecting all LEDs in one circuit include reducing a number of solder joints required. In this regard, reducing the number of solder joints cumulates in a higher yield, as every solder joint poses a risk of yield loss. Further, connecting all LEDs in one circuit improves robustness, as less solder joints can potentially fail during stress testing/in the field, and, in consequence, lower cost to produce and maintain the product.

One or more technical effects, advantages, and benefits of the flexible foil PCB substrate include a thinner total build-up as the flexible foil PCB substrate is thin and components are placed mainly on one side. Further, due to the thinner total build-up, the flexible foil PCB substrate improves heat management of the thin light source created.

One or more technical effects, advantages, and benefits of the flexible foil PCB substrate include controlling the LED-to-LED pitch distance and omitting the custom made, special formed wire based conventional technology solutions. That is, the custom made, special formed wire based conventional technology solutions are complex by design and to manufacture, which causes a required tolerance in front-end assembly hard to control. Placement accuracy strongly depends on total tolerances, and the flexible foil PCB substrate enables relative easier control.

According to one or more embodiments, the flexible foil printed circuit board substrate can include at least one metal layer. Further, any one of the at least one metal layers can be a copper layer. Further, each of the at least one metal layers can include one or more electrical lines. The one or more electrical lines can form an electrical circuit within the flexible foil PCB substrate. At least one electrical via can connect the one or more electrical lines of the metal layers. In an example, one copper layer can include three electrical lines. In another example, each of two copper layers can include one or two electrical lines connected by electrical vias. According to one or more embodiments, one layer with three electrical lines can be implemented, as well as two layers electrical lines per layer.

According to one or more embodiments, the flexible foil PCB substrate can include two or more connecting structures that partition the surface mounting technology components into one or more groups. Each of the one or more groups can be independently controlled into on and off states by controllers. By way of example, the surface mounting technology components can comprise a single static group. By way of further example, the surface mounting technology components can include at least two groups that dynamically operate. For instance, groups of LEDs can be connected in a top metal layer. The top metal layer can be interrupted at a place where the LEDs are placed over a gap formed. The groups of LEDs can be separated from each other in the gaps of the top metal layer. The gaps can be smaller in comparison to a distance between the lands (e.g., such that a mechanical stiffness between lands where metal layers are powered is comparable, the same, or close to the same as those not powered.

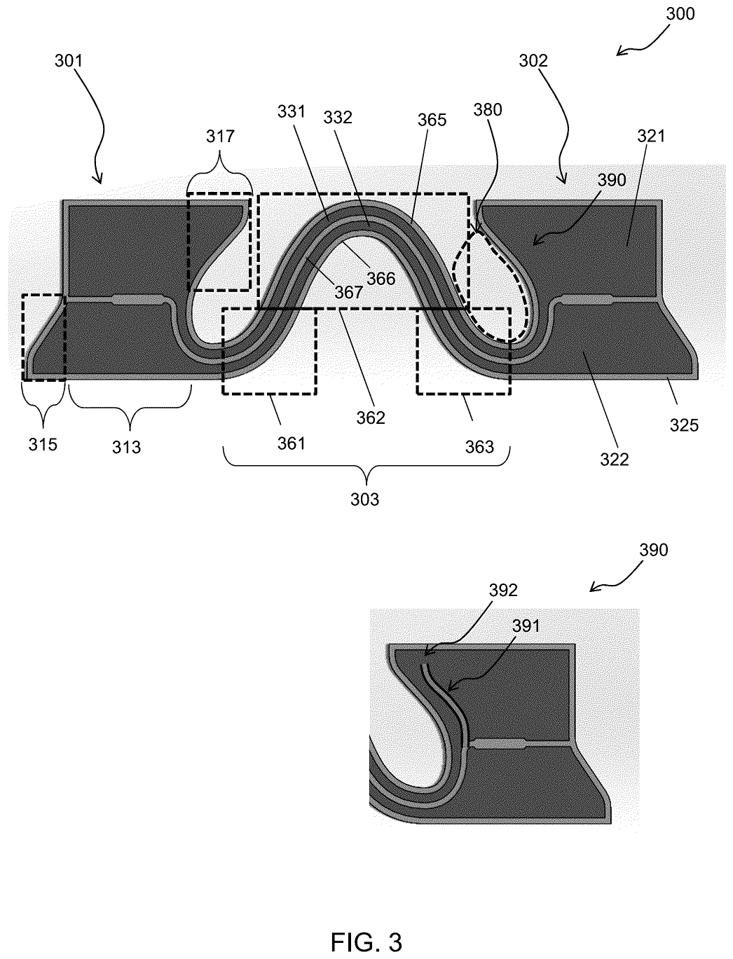

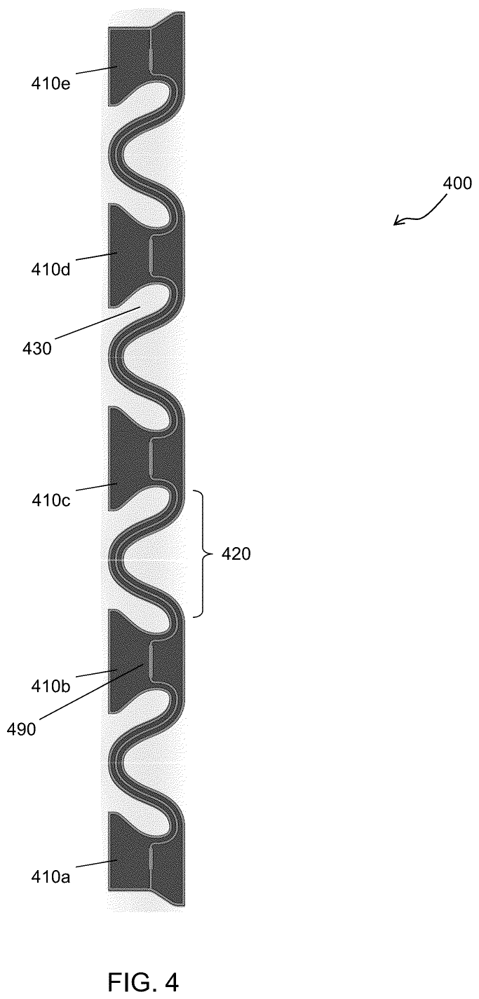

Turning now to FIGS. 3-4, the flexible foil PCB substrate is further described according to one or more embodiments. According to one or more embodiments, the flexible foil PCB substrate can be constructed such that an area between lands include any number of shapes to mimic winding river, serpentine or snake-like, parabolic, ellipsoidal, and/or sinusoidal shapes/geometries. Further, the lands of the flexible foil PCB substrate can be of any shape as well.

FIG. 3 shows a schematic 300 of the flexible foil PCB substrate according to one or more embodiments. According to one or more embodiments, the flexible foil PCB substrate can be one piece. According to one or more embodiments, the flexible foil PCB substrate can be embedded in a silicone matrix. The schematic 300 includes a first land 301, a second land 302, and a flex foil area 303.

The first and second lands 301 and 302 can include a first section 313, a second section 315, and a third section 317. The first and second lands 301 and 302 can include conductive portions 321 and 322. The first and second lands 301 and 302 can include electrical vias to connect the conductive portions 321 and 322 to any surface of the flexible foil PCB substrate.

The first and second lands 301 and 302 can be any shape/geometry, such as rectangular or an irregular shape. For example, the first and second lands 301 and 302 can include a central body of a rectangular shape that has one or more peninsulas (e.g., represented by the second and third sections 315) extending from central body. The one or more peninsulas can form bays 380 or like opening, as described herein. The first and second lands 301 and 302 can be configured to receive with respect to the conductive portions 321 and 322 a placement of SMT components (e.g., the LEDs, microcontrollers, etc.). According to one or more embodiments, one or multiple LEDs can be present on a first side of the first and second lands 301 and 302. According to one or more embodiments, at least one connecting structure can be present on at least one of a second side of the first and second lands 301 and 302 to enable an electrical connection of the one or multiple LEDs to a power source.

According to one or more embodiments, the first section 313 can be rectangular or square lands for the placement of SMT components. The second and third sections 315 and 317 can protrude from the first section 313. A shape of the second and third sections 315 can correspond to a shape of the flex foil area 303 (e.g., irregular shapes of the lands can include protruding sections that match the outermost ends of the flex foil area). One or more technical effects, benefits, or advantages of the shape of the second and third sections 315 corresponding to the shape of the flex foil area 303 includes eliminating electrical interference, electromagnetic interference, radio-frequency interference, electromagnetic induction, electrostatic coupling, or the like. Further, an outer border 325 can define or characterize the first and second lands 301 and 302. The outer border 325 can include a non-conductive material.

The flex foil area 303 can be a portion of the flexible foil PCB substrate between the first and second lands 301 and 302 (pairs of the two or more lands). The flex foil area 303 can include multiple layers, such as multiple copper layers. Each layers can contain electrical lines to form an electrical circuit with the first and second lands 301 and 301. For instance, the flex foil area 303 can include a first conductive material 331 and a second conductive material 332 that correspondingly connect the conductive portions of the first and second lands 301 and 302. The flex foil area 303 can include electrical vias to connect the electrical lines to any surface of the flex foil area 303. The flex foil area 303 can include any number of curved shapes to mimic winding river, serpentine or snake-like, parabolic, ellipsoidal, and/or sinusoidal shapes/geometries. According to one or more embodiments, the groups or sequences can have final positions, such as up-up-up when a bend is upwards and down-down-down when being bend downwards.

According to one or more embodiments, the flex foil area 303 includes sinusoidal formed bends (e.g., the bends substantially follow a half-sine path). According to one or more embodiments, the flex foil area 303 includes semi-circular formed bends or semi-elliptical formed bends (e.g., the bends substantially follow a semi-circle path or a semi-elliptical path). For instance, the flex foil area 303 can include at least three (3) semi-circular bends, such as five (5), to withstand automotive reliability requirements (e.g., in low voltage automotive lighting applications). According to one or more embodiments, the a shape or a path of the flex foil area 303 is selected according to a bend direction in an application.

According to one or more embodiments, the flex foil area 303 includes parabolic formed bends (e.g., the bends substantially follow a parabolic curve path). For instance, the flex foil area 303 can include three (3) parabolic formed bends to withstand automotive reliability requirements (e.g., in low voltage automotive lighting applications). According to one or more embodiments, the flex foil area 303 includes a combination of sinusoidal formed bends, semi-circular formed bends, semi-elliptical formed, and parabolic formed bends.

By way of example, the flex foil area 303 can includes three bent segments connecting the lands 301 and 302 (though no limited thereto). As shown in FIG. 3, the flex foil area 303 includes three bent segments 361, 362, and 363 (i.e., curved or bent portions of the flex foil area 303). Further, the flex foil area 303 can define or characterize outer borders 365 and 366 and an inner border 367 of the bent segments. The outer borders 365 and 366 and the inner border 367 can include a non-conductive material. According to one or more embodiments, as shown in an alternative schematic 390 and by an extension 391, the inner border 367 can extend to the outer borders 356 and 366 within the lands 301 and 302. For example, the flexible foil PCB substrate can prolong an electrical line (e.g., the extension 391) to an end of the bay 380, leaving a gap 392 for an electrical current. This configuration can change a bow shape and relax stresses during thermal cycling.

The bent segments 361 (e.g., an outermost bent area segment) can be partially integrated into the first land 301. The bent segments 363 (e.g., an outermost bent area segment) can be partially integrated into the second land 302. The inner border 367 of the flex foil area 303 continues into the first and second lands 301 and 302. According to one or more embodiments, and as shown in FIG. 3, the flex foil area 303 can curve into the first and second lands 301 and 302 (e.g., swing around substantially mirroring the half-sine or parabolic path) an angle of 35-40 degrees) to form the bay 380 or like opening. Thus, the outer borders 365 and 366 continues as the outer boards 325 of the first and second lands 301 and 302. One or more technical effects, benefits, or advantages of the shape of the bay 380 with respect to the second and third sections 315 includes eliminating electrical interference, electromagnetic interference, radio-frequency interference, electromagnetic induction, electrostatic coupling, or the like. According to one or more embodiments, the bay 380 can be required to be a specific shape/geometry, such as that shown by the dashed line in FIG. 3. Further, other shapes/geometries for the bay 380 are contemplated, such as squares, circles, eggs, crescents, ellipses, circular triangle, etc. Note that a properly shaped bay 380 may be required for the schematic 300 to electrically function. According to one or more embodiments, a small bay 380 can relax stress of the flexible automotive grade light source in conjunction with a three bend approach and the LED to LED pitches in a range of 10 to 25 mm. According to one or more embodiments, an extreme bay 380 can relax stress of the flexible automotive grade light source in conjunction with a one bend approach and the LED to LED distances at or below 15 mm.

FIG. 4 shows a schematic 400 of the flexible foil PCB substrate (e.g., parabolic shaped thin film flexible foil PCBA) according to one or more embodiments. According to one or more embodiments, the flexible foil PCB substrate can be one piece. According to one or more embodiments, the flexible foil PCB substrate can be embedded in a silicone matrix.

The flexible foil PCB substrate according to the schematic 400 depicts a repeating pattern and can incorporate the properties of the schematic 300, as described herein. The flexible foil PCB substrate according to the schematic 400 can be used in low voltage automotive lighting applications, The schematic 400 includes a plurality of lands 410, a plurality of flex foil areas 420, and a plurality of bays 430. The plurality of flex foil areas 420 utilizes parabolic shapes (e.g., bows pointing in a same direction). According to one or more embodiments, the plurality of flex foil areas 420 can include an amplitude that is less than or equal to a height of the plurality of lands 410. One or more technical effects, benefits, or advantages of the structure of the schematic 400 includes decreasing an LED to LED pitch with respect to the plurality of lands 410 from greater than 20 mm to at or lower than 20 mm, such as 12 mm or lower.

According to one or more embodiments, adjacent segments of the plurality of flex foil areas 420 can mirror (along a length of the flexible foil PCB substrate) neighboring segments joint at lines connecting ends of inner and outer boarders, such as in shortest manner. By way of example, outermost bent area segments of the flex foil areas 420 can be partially integrated into adjacent lands 420, such that inner border continue into the adjacent lands 420 by swinging around to substantially mirror a half-sine or parabolic line at an angle of 35-40 degrees and forming a bay like opening. By further way of example, integrating the outermost bent area segments of the flex foil areas 420 into adjacent lands 420 can include bringing/continuing outer borders of the flex foil areas 420 to outer borders of the lands 420, which is followed by a spiral of opposite turning direction to connect the integrated segments inner border line with the outer side of the land (as shown in FIGS. 3 and 4). The outer borders of the flex foil areas 420 smoothly transitions into top and bottom outer borders of the lands 420, respectively. The flexible foil PCB substrate according to the schematic 400 depicts a horizontal spacer 490 over an area of the lands 410 on which LEDs are placed.

According to one or more embodiments, a connecting structure can be present on a second side or a backside of one of the outermost land 410a or 410e (of the plurality of lands 410). According to one or more embodiments, two or more connecting structures can be present on second sides of one or more of the two outermost lands 410a or 410e (of the plurality of lands 410). According to one or more embodiments, a connecting structure can be present on a second side of the flexible foil PCB substrate in between two outermost lands 410a or 410e (of the plurality of lands 410). According to one or more embodiments, a connecting structure can be present on a second side of interior lands 410b, 410c, or 410d (of the plurality of lands 410). According to one or more embodiments, a connecting structure can be present on a second side of the flexible foil PCB substrate in between any of the plurality of lands 410.

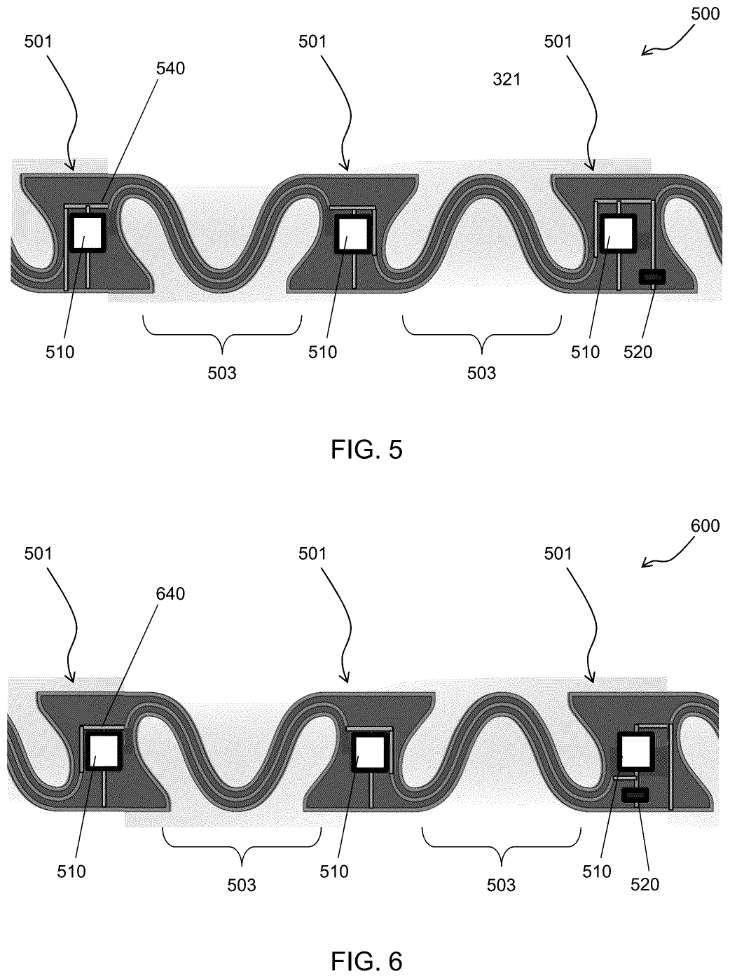

Turning to FIGS. 5-8, example schematics of the flexible foil PCB substrate are shown according to one or more embodiments. Note that the flexible foil PCB substrate can be one piece, embedded in a silicone matrix, and/or comprises any combination of shapes/geometries as described herein. Note that the example schematics of the FIGS. 5-8 are showing a portion of a total flexible foil PCB substrate. Items, elements, and identifiers are reused for brevity and are not reintroduced across the FIGS. 5-8.

FIG. 5 shows a schematic 500 of the flexible foil PCB substrate according to one or more embodiments. The schematic 500 includes a plurality of lands 501 and flex foil areas 503. The flex foil areas 503 depicts an up-down-up-down pattern (i.e., switching directions, such as symmetric bows alternating up and down), while a same facing direction pattern is also contemplated. The schematic 500 includes a plurality of LEDs 510 and a balancing resistor 520. The LEDs 510 can be grouped as described herein. The balancing resistor 520 can be at an end of one of the LEDs segments/groups. As shown in FIGS. 5-8, the balancing resistor 520 can be located at one of multiple locations within the segment of the LEDs, such as within a vertical LED gap or a horizontal placement with a flipped LED. Thus, the balancing resistor 520 can be placed, as shown, within an LED sequence of one segment or at either end. The balancing resistor 520 can also be on a next land with no LED belonging to a corresponding segment (with an exception being the first or last land). Further, the schematic 600 can be defined or characterized by borders, such as the inner border 540 (e.g., an electrical line interruption) that partitions the lands 501 into conductive areas for receiving the LEDS 510. According to one or more embodiments, the electrical line interruption for the segments can be on the lands 501 and to provide symmetric mechanical properties along the schematic 500. The electrical line interruption could also be on a land 501 that does not belong to an LED segment.

According to one or more embodiments, in the schematic 500, the LEDs 510 can be placed in parallel. Note that, because parallel placement can include issues with respect to high current limits (i.e., that are not permitting to surpass), the schematic 500 can be a “dynamic” embodiment that segments or groups the LEDs 510 in series. For example, if the schematic includes thirty (30) LEDs 510, then the LEDs 510 can be wired in in five (5) or six (6) groups (e.g., five (5) parallel groups of six (6) LEDs 510 in series) Note that every segment can be operated (e.g., turned on or off) independently. Alternatively, a “static” embodiment can wire the segments in series, with the LEDS 510 therein connected in parallel.

According to one or more embodiments, the balancing resistor 520 is utilized on a per segment/group basis (e.g., to address currents running through any one segment). By way of example, whether a static or dynamic embodiment is utilized, both approaches can meet requirement for an end product, such as operating below 48 Volts for low voltage directives and managing currents below 2 Amps. The LEDs 510 can be three LEDs in series as white and two for red, which provide ˜9V and ˜6V forward voltage respectively (i.e., below a standard car battery level and no requirement for boost converter to drive the products). Note that LEDs are normally operated at constant current.

FIG. 6 shows a schematic 600 of the flexible foil PCB substrate according to one or more embodiments. The schematic 600 depicts the flex foil areas 503 as an up-down-up-down pattern. Further, the schematic 600 can be defined or characterized by borders, such as the inner border 640 (e.g., an electrical line interruption) that partitions the lands 501 into conductive areas for receiving the LEDS 510.

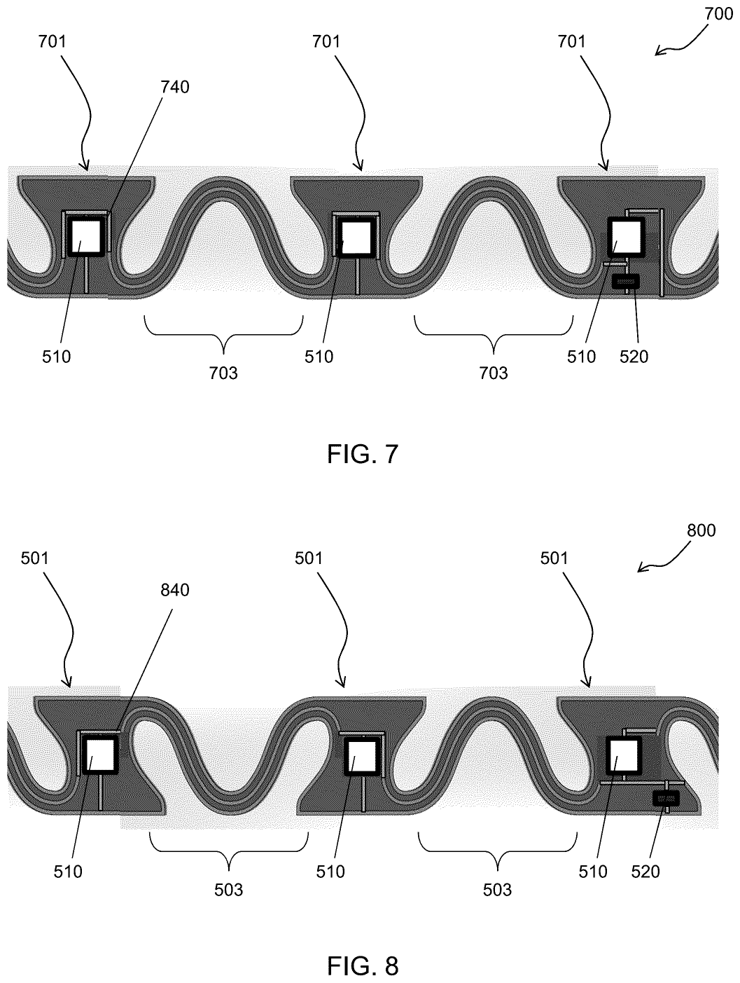

FIG. 7 shows a schematic 700 of the flexible foil PCB substrate according to one or more embodiments. The schematic 700 includes a plurality of lands 701 and flex foil areas 703. The flex foil areas 703 depicts an up or down (i.e., same facing direction) pattern. Further, the schematic 700 can be defined or characterized by borders, such as the inner border 740 (e.g., an electrical line interruption) that partitions the lands 701 into conductive areas for receiving the LEDS 710.

FIG. 8 shows a schematic 800 of the flexible foil PCB substrate according to one or more embodiments. The schematic 800 can be defined or characterized by borders, such as the inner border 840 (e.g., an electrical line interruption) that partitions the lands 501 into conductive areas for receiving the LEDS 510. The schematic 800 can include one conductive line available in a top layer for electrical contacting, only one electrical line, or three conductive lines in a top layer.

According to one or more embodiments and in view of the contents herein, a flexible foil printed circuit board substrate is provided. The foil printed circuit board substrate includes at least first and second lands. Each of the first and second lands being configured to receive a placement of one or more surface mounting technology components. The foil printed circuit board substrate also includes a flex foil area between pairs of the at least first and second lands. The flex foil area includes at least one layer including at least one conductive portion connecting the at least first and second lands (e.g., at least two layers including conductive portions). The flex foil area includes one or more curved shapes. Note that an outermost ends of the flex foil area can be integrated into the at least first and second lands.

According to one or more embodiments, the one or more surface mounting technology components can include one or more light emitting diodes placed on a first side of the two or more lands. The at least one conductive portion can electrically connect the one or more light emitting diodes in series and/or to an electrical power source or electrical driver. The one or more surface mounting technology components can include at least two groups of at least two light emitting diodes connected in series, whereby the at least two groups are electrically connected to an electrical power source or driver each. According to one or more embodiments, each of the at least two groups is independently controlled. The at least one conductive portion can include at least three conductive portions connecting the at least first and second lands. The at least three conductive portions can include at least two conductive layers of the flexible foil printed circuit board substrate.

The one or more surface mounting technology components can include at least two groups of at least two light emitting diodes connected in parallel to an electrical power source or driver. Each group of the at least two groups can include at least one resistor connected in series to at least one of the light emitting diodes of that group. The at least two groups of light emitting diodes can collectively controlled. Note that, per group of light emitting diodes, at least one resistor can be located on a land together with one light emitting diode of said group of light emitting diodes. At least one resistor of a group of light emitting diodes can be located on a land distant to the light emitting diodes belonging to said group of light emitting diodes and/or on a land together with a light emitting diode belonging to another group of light emitting diodes of the at least two groups.

According to one or more embodiments, the one or more surface mounting technology components can include microcontrollers. According to one or more embodiments, the flexible foil printed circuit board substrate can be configured for use in automotive lighting applications. According to one or more embodiments, the flexible foil printed circuit board substrate can be embedded in a silicone matrix of a silicone based slim elongated flexible automotive grade light source. Light emitting areas of the one or more surface mounting technology components can be in direct contact with a silicone matrix. The silicone matrix forms a mixing box can be at least three reflecting sides and at least one light extraction side covered by a diffuse silicone. The one or more surface mounting technology components couple light into the mixing box via holes in one of the at least three reflecting sides. According to one or more embodiments, the silicone can include a wavy structure with a maximum thickness above the one or more surface mounting technology components and minimum thickness between the one or more surface mounting technology components that homogenizes light output from the one or more surface mounting technology components. The flex foil area can include five bent sections comprising first and second outer sections and three inner sections. According to one or more embodiments, adjacent segments of the at least three bent sections can be horizontally flipped relative to the previous or next section. The flexible foil printed circuit board substrate can comprise a single piece.

According to one or more embodiments, the at least two layers can include two or more metal layers. Each metal layer can include two or less electrical lines to form an electrical circuit within the flexible foil printed circuit board substrate. The flexible foil printed circuit board substrate can include at least one electrical via to connect the two or less electrical lines of the flexible foil printed circuit board substrate through the two or more metal layers. The flexible foil printed circuit board substrate can include at least one connecting structure on at least one of a backside of one of the two or more lands for electrically connecting the one or more surface mounting technology components to a power source.

According to one or more embodiments, the at least one connecting structure can include a rigid PCB mounted on a backside of at least one of the two or more lands of the flexible foil. The at least one connecting structure can be on a backside of an outermost land of the two or more lands. A geometry of the flexible foil printed circuit board substrate can be defined by a cutting or punching process. The at least first and second lands can include irregular geometries that include protruding sections that match the outermost ends of the flex foil area. The flexible foil printed circuit board substrate can include a plurality of bays between the at least first and second lands and the flex foil area. The flex foil area can include three (3) parabolic formed bends or five (5) semi-circular formed or semi-elliptical formed bends. The flex foil area can include an amplitude that is less than or equal to a height of the at least first and second lands. A shape or path of the flex foil area can mimic a winding river, serpentine, parabolic, ellipsoidal, or sinusoidal geometry. A shape or a path of the flex foil area can be selected according to a bend direction. The at least first and second lands can include rectangular shapes. The at least first and second lands can include irregular shapes with at least one peninsula extending from a central body. The flexible foil printed circuit board substrate can include a plurality of bays between the at least first and second lands and the flex foil area. At least one bay of the plurality of bays can include a square, circle, egg, crescent, ellipse, or circular triangle geometry. The flex foil can include one or more non-conductive borders that partitions conductive portions of the flex foil. The one or more non-conductive borders can include outer borders and an inner border that extend to the outer borders to partition the conductive portions of the flex foil area.

According to one or more embodiments and in view of the contents herein, a flexible automotive grade light source is provided. The foil printed circuit board substrate includes at least first and second lands. Each of the first and second lands being configured to receive a placement of one or more surface mounting technology components. The foil printed circuit board substrate also includes a flex foil area between pairs of the at least first and second lands. The flex foil area includes at least one layer including at least one conductive portion connecting the at least first and second lands The flex foil area includes one or more curved shapes. Note that an outermost ends of the flex foil area can be integrated into the at least first and second lands. The flexible foil printed circuit board substrate can be embedded in a silicone matrix of the flexible automotive grade light source.

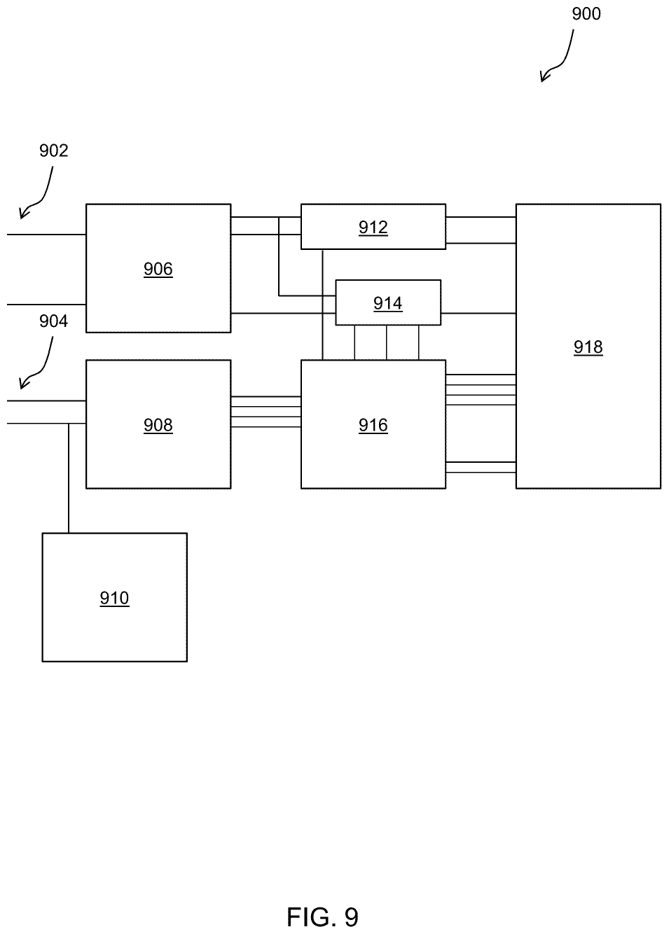

FIG. 9 is a diagram of an example vehicle headlamp system 900 that may incorporate one or more of the embodiments and examples described herein. The example vehicle headlamp system 900 illustrated in FIG. 9 includes power lines 902, a data bus 904, an input filter and protection module 906, a bus transceiver 908, a sensor module 910, an LED direct current to direct current (DC/DC) module 912, a logic low-dropout (LDO) module 914, a micro-controller 916, and an active head lamp 918.

The power lines 902 may have inputs that receive power from a vehicle, and the data bus 904 may have inputs/outputs over which data may be exchanged between the vehicle and the vehicle headlamp system 900. For example, the vehicle headlamp system 900 may receive instructions from other locations in the vehicle, such as instructions to turn on turn signaling or turn on headlamps, and may send feedback to other locations in the vehicle if desired. The sensor module 910 may be communicatively coupled to the data bus 904 and may provide additional data to the vehicle headlamp system 900 or other locations in the vehicle related to, for example, environmental conditions (e.g., time of day, rain, fog, or ambient light levels), vehicle state (e.g., parked, in-motion, speed of motion, or direction of motion), and presence/position of other objects (e.g., vehicles or pedestrians). A headlamp controller that is separate from any vehicle controller communicatively coupled to the vehicle data bus may also be included in the vehicle headlamp system 900. In FIG. 9, the headlamp controller may be a micro-controller, such as micro-controller (pc) 916. The micro-controller 916 may be communicatively coupled to the data bus 904.

The input filter and protection module 906 may be electrically coupled to the power lines 902 and may, for example, support various filters to reduce conducted emissions and provide power immunity. Additionally, the input filter and protection module 906 may provide electrostatic discharge (ESD) protection, load-dump protection, alternator field decay protection, and/or reverse polarity protection.

The LED DC/DC module 912 may be coupled between the input filter and protection module 106 and the active headlamp 918 to receive filtered power and provide a drive current to power LEDs in the LED array in the active headlamp 918. The LED DC/DC module 912 may have an input voltage between 9 and 18 volts with a nominal voltage of approximately 13.2 volts and an output voltage that may be slightly higher (e.g., 0.3 volts) than a maximum voltage for the LED array (e.g., as determined by factor or local calibration and operating condition adjustments due to load, temperature or other factors).

The logic LDO module 914 may be coupled to the input filter and protection module 906 to receive the filtered power. The logic LDO module 914 may also be coupled to the micro-controller 916 and the active headlamp 918 to provide power to the micro-controller 916 and/or electronics in the active headlamp 918, such as CMOS logic.

The bus transceiver 908 may have, for example, a universal asynchronous receiver transmitter (UART) or serial peripheral interface (SPI) interface and may be coupled to the micro-controller 916. The micro-controller 916 may translate vehicle input based on, or including, data from the sensor module 910. The translated vehicle input may include a video signal that is transferrable to an image buffer in the active headlamp 918. In addition, the micro-controller 916 may load default image frames and test for open/short pixels during startup. In embodiments, an SPI interface may load an image buffer in CMOS. Image frames may be full frame, differential or partial frames. Other features of micro-controller 916 may include control interface monitoring of CMOS status, including die temperature, as well as logic LDO output. In embodiments, LED DC/DC output may be dynamically controlled to minimize headroom. In addition to providing image frame data, other headlamp functions, such as complementary use in conjunction with side marker or turn signal lights, and/or activation of daytime running lights, may also be controlled.

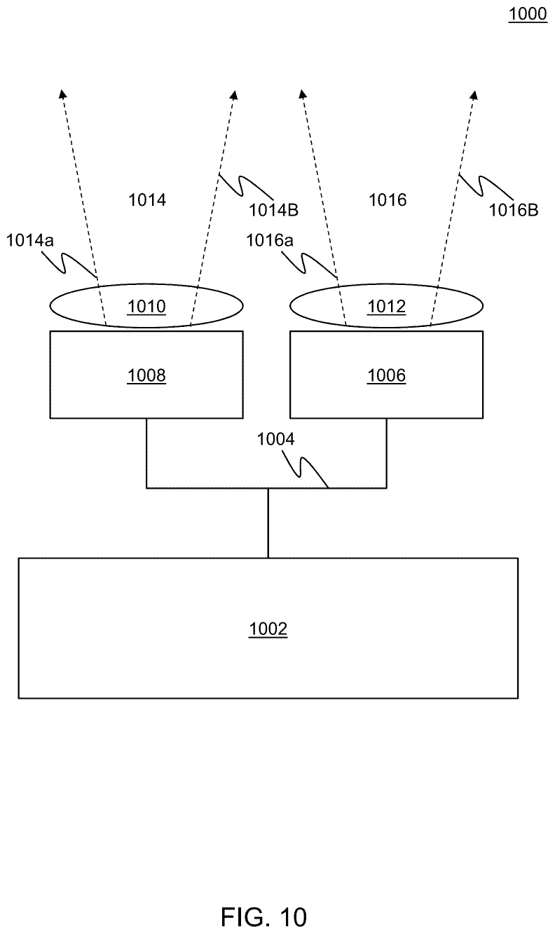

FIG. 10 is a diagram of another example vehicle headlamp system 1000. The example vehicle headlamp system 1000 illustrated in FIG. 10 includes an application platform 1002, two LED lighting systems 1006 and 1008, and secondary optics 1010 and 1012.

The LED lighting system 1008 may emit light beams 1014 (shown between arrows 1014a and 1014b in FIG. 10). The LED lighting system 1006 may emit light beams 1016 (shown between arrows 1016a and 1016b in FIG. 10). In the embodiment shown in FIG. 10, a secondary optic 1010 is adjacent the LED lighting system 1008, and the light emitted from the LED lighting system 1008 passes through the secondary optic 1010. Similarly, a secondary optic 1012 is adjacent the LED lighting system 1006, and the light emitted from the LED lighting system 1006 passes through the secondary optic 1012. In alternative embodiments, no secondary optics 1010/812 are provided in the vehicle headlamp system.

Where included, the secondary optics 1010/812 may be or include one or more light guides. The one or more light guides may be edge lit or may have an interior opening that defines an interior edge of the light guide. LED lighting systems 1008 and 1006 may be inserted in the interior openings of the one or more light guides such that they inject light into the interior edge (interior opening light guide) or exterior edge (edge lit light guide) of the one or more light guides. In embodiments, the one or more light guides may shape the light emitted by the LED lighting systems 1008 and 1006 in a desired manner, such as, for example, with a gradient, a chamfered distribution, a narrow distribution, a wide distribution, or an angular distribution.

The application platform 1002 may provide power and/or data to the LED lighting systems 1006 and/or 1008 via lines 1004, which may include one or more or a portion of the power lines 902 and the data bus 904 of FIG. 9. One or more sensors (which may be the sensors in the vehicle headlamp system 1000 or other additional sensors) may be internal or external to the housing of the application platform 1002. Alternatively, or in addition, as shown in the example vehicle headlamp system 900 of FIG. 9, each LED lighting system 1008 and 1006 may include its own sensor module, connectivity and control module, power module, and/or LED array.

In embodiments, the vehicle headlamp system 1000 may represent an automobile with steerable light beams where LEDs may be selectively activated to provide steerable light. For example, an array of LEDs or emitters may be used to define or project a shape or pattern or illuminate only selected sections of a roadway. In an example embodiment, infrared cameras or detector pixels within LED lighting systems 1006 and 1008 may be sensors (e.g., similar to sensors in the sensor module 910 of FIG. 9) that identify portions of a scene (e.g., roadway or pedestrian crossing) that require illumination.

As would be apparent to one skilled in the relevant art, based on the description herein, embodiments of the present invention can be designed in software using a hardware description language (HDL) such as, for example, Verilog or VHDL. The HDL-design can model the behavior of an electronic system, where the design can be synthesized and ultimately fabricated into a hardware device. In addition, the HDL-design can be stored in a computer product and loaded into a computer system prior to hardware manufacture.

Having described the embodiments in detail, those skilled in the art will appreciate that, given the present description, modifications may be made to the embodiments described herein without departing from the spirit of the inv concept. Therefore, it is not intended that the scope of the invention be limited to the specific embodiments illustrated and described.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

What is claimed is:

1. A flexible foil printed circuit board substrate comprising:
at least first and second lands, each of the first and second lands being configured to receive a placement of one or more surface mounting technology components; and
a flex foil area between pairs of the at least first and second lands, the flex foil area comprising at least one layer including at least one conductive portion connecting the at least first and second lands,
wherein the flex foil area comprises one or more curved shapes, and
wherein outermost ends of the flex foil area are integrated into the at least first and second lands.

2. The flexible foil printed circuit board substrate of claim 1, wherein the one or more surface mounting technology components comprise one or more light emitting diodes placed on a first side of the two or more lands, and
wherein the at least one conductive portion electrically connects the one or more light emitting diodes in series.

3. The flexible foil printed circuit board substrate of claim 1, wherein the one or more surface mounting technology components comprise at least two groups of at least two light emitting diodes connected in series, whereby the at least two groups are electrically connected to an electrical power source or driver each

4. The flexible foil printed circuit board substrate of claim 1, wherein the one or more surface mounting technology components comprise at least two groups of at least two light emitting diodes connected in parallel to an electrical power source or driver, and
wherein each group of the at least two groups comprises at least one resistor connected in series to at least one of the light emitting diodes of that group.

5. The flexible foil printed circuit board substrate of claim 1, wherein the at least one connecting structure comprises a rigid printed circuit board mounted on a backside of at least one of the two or more lands of the flexible foil.

6. The flexible foil printed circuit board substrate of claim 1, wherein the at least first and second lands comprise irregular geometries that include protruding sections that match the outermost ends of the flex foil area.

7. The flexible foil printed circuit board substrate of claim 1, wherein the flexible foil printed circuit board substrate comprises a plurality of bays between the at least first and second lands and the flex foil area.

8. The flexible foil printed circuit board substrate of claim 7, wherein at least one bay of the plurality of bays comprise a square, circle, egg, crescent, ellipse, or circular triangle geometry

9. The flexible foil printed circuit board substrate of claim 1, wherein the flex foil area comprises three (3) parabolic formed bends.

10. The flexible foil printed circuit board substrate of claim 1, wherein the flex foil area comprises five (5) semi-circular formed or semi-elliptical formed bends.

11. The flexible foil printed circuit board substrate of claim 1, wherein the flex foil area comprises an amplitude that is less than or equal to a height of the at least first and second lands.

12. The flexible foil printed circuit board substrate of claim 1, wherein the at least first and second lands comprise rectangular shapes.

13. The flexible foil printed circuit board substrate of claim 1, wherein the at least first and second lands comprise irregular shapes with at least one peninsula extending from a central body.

14. The flexible foil printed circuit board substrate of claim 1, wherein the flex foil comprises one or more non-conductive borders that partitions conductive portions of the flex foil.

15. The flexible foil printed circuit board substrate of claim 14, wherein the one or more non-conductive borders comprise outer borders and an inner border that extend to the outer borders to partition the conductive portions of the flex foil area.

16. A flexible automotive grade light source comprising a flexible foil printed circuit board substrate comprising:
at least first and second lands, each of the first and second lands being configured to receive a placement of one or more surface mounting technology components; and
a flex foil area between pairs of the at least first and second lands, the flex foil area comprising at least two layers including conductive portions connecting the at least first and second lands,
wherein the flex foil area comprises one or more curved shapes, and
wherein outermost ends of the flex foil area are integrated into the at least first and second lands.

17. The flexible automotive grade light source of claim 16, wherein the flexible foil printed circuit board substrate is embedded in a silicone matrix of the flexible automotive grade light source.

18. The flexible automotive grade light source of claim 16, wherein the flex foil area comprises five bent sections comprising first and second outer sections and three inner sections.

19. The flexible automotive grade light source of claim 16, wherein adjacent segments of the at least three bent sections are horizontally flipped relative to the previous or next section.

20. The flexible automotive grade light source of claim 16, wherein a shape or path of the flex foil area comprises a winding river, serpentine, parabolic, ellipsoidal, or sinusoidal geometry.
